(19) United States
(12) Patent Application Publication
(10) Pub. No.: US 2008/0258318 A1
(43) Pub. Date: Oct. 23, 2008

(54) Semiconductor device

(75) Inventor: Naoto Kimura, Fukuoka (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/081,666

(22) Filed: Apr. 18, 2008

(30) Foreign Application Priority Data
Apr. 20, 2007 (JP) 111218/2007
Mar. 28, 2008 (JP) 87750/2008

(51) Int. Cl. H01L 23/29; H01L 23/28

(52) U.S. Cl. 257/793; 257/788; 257/E23.119; 257/E23.116

(57) ABSTRACT

Disclosed herewith is a semiconductor device capable of suppressing the peeling-off that might occur between an island and a resin layer due to a difference of the shrinkage between those items, thereby the reliability of the semiconductor device is improved. The semiconductor device of the present invention includes an island, a semiconductor chip mounted on the island, and a resin layer that seals the island and the semiconductor chip respectively. And at the interface between the island and the resin layer is provided a buffer film having an elastic modulus lower than that of the resin layer.

### BACKGROUND OF THE INVENTION

1. Field of the Invention

The present invention relates to a semiconductor device having a semiconductor chip mounted on an island.

2. Description of the Related Art

There are some semiconductor devices as described in JP-A-2000-307049, JP-A-06-204362, and JP-A-04-154155.

JP-A-2000-307049 discloses a semiconductor device including a metal island 130 having ring-like grooves 132 and 134 as shown in FIG. 9. JP-A-2000-307049 describes that the grooves 132 and 134 are effective to increase the contact area between the island 130 and mold resin, thereby the adhesion between those items is improved. Furthermore, JP-A-2000-307049 describes that the groove 134 can suppress the peeling-off between those items.

JP-A-06-204362 discloses a semiconductor device that includes a metal island 136, a semiconductor chip 138 mounted on the metal island 136, a crushing filler included polyimide film 140, and a mold resin layer 142 that buries all those items. JP-A-06-204362 describes that the surface of the polyimide film 140 is roughened, thereby the adhesion between the semiconductor chip 138 and the mold resin layer 142 is improved.

JP-A-04-154155 discloses a semiconductor device that includes a metal island 146 having a groove 144 (or jetty) formed so as to surround a semiconductor chip 148, a semiconductor chip 148 mounted on the metal island 146 through a mounting material 150, and a mold resin layer 152 that seals those items. JP-A-04-154155 describes that the groove 144 (or jetty) is effective to suppress the flow of the mounting material to the periphery.

### SUMMARY

However, each of the conventional techniques disclosed in the above documents has been confronted with the following problems.

In case of the semiconductor device including the grooves 132 and 134 described in JP-A-2000-307049, if there is a stress that exceeds the adhesion between the groove and the resin, it is difficult to prevent the peeling-off between the mold resin layer and the metal island 130.

In case of the semiconductor device disclosed in JP-A-06-204362, if thermal shrinkage occurs in the metal island 136 and in the mold resin layer respectively, they are often separated from each other.

In case of the semiconductor device disclosed in JP-A-04-154155, the metal island 146 and the mold resin layer 152 are apt to be separated from each other at side surfaces of the metal island 146.

Hereunder, there will be described the reasons why the metal island and the mold resin layer are separated from each other such way in the conventional semiconductor devices as described above.

As shown in FIG. 8, a semiconductor device 100 includes a semiconductor chip 116 mounted on the surface of a metal island 112 and the chip 116 and the metal island 112 are buried in a mold resin layer 124. The semiconductor chip 116 is mounted on the top face of the metal island 112 through a mounting material of which area is approximately the same as that of the semiconductor chip 116.

The semiconductor device 116 might stop its operation, malfunction, or be damaged if its temperature rises due to a heat generated from the semiconductor chip. And this heat generated from the semiconductor chip 116 is required to be radiated through the metal island 112.

The shrinkage ratio of the mold resin layer 124 differs significantly from that of the metal material such as copper used for the metal island 112. Consequently, if the heat generation from the semiconductor chip 116 is reduced and the temperature of the semiconductor device 100 falls, such a shrinkage ratio difference causes peeling-off 126 at the interface between the mold resin layer 124 and the metal island 112. Particularly, the peeling-off 126 appears remarkably in the horizontal direction in which the metal island 112 shrinks more.

If such temperature changes of the semiconductor device 100 are repeated after that, this peeling-off 126 advances upward and in the horizontal direction from an end face of the device 100. If the peeling-off 126 advances upward, the peeling-off 126 comes to cut wires. If the peeling-off 126 advances in the horizontal direction, it might cause peeling-off between the mold resin layer 124 and the metal island 112, thereby the heat radiation from the semiconductor chip might be lowered during operation. If the downward peeling-off of the semiconductor chip 116 further advances, water might come in through the peeling-off point, thereby damaging the semiconductor chip 116.

If a metal island 112 having an area larger than the semiconductor chip is used, the metal island 112 comes to shrink more in the horizontal direction, thereby the contact area between the surface of the metal island 112 and the mold resin layer 124 increases. Thus the peeling-off at the interface appears more remarkably.

Under such circumstances, it is an object of the present invention to provide a semiconductor device, which includes a metal island, a semiconductor chip mounted on the metal island, and a mold resin layer that seals the metal island and the semiconductor chip respectively. And a buffer film is formed at the interface between side faces of the metal island and the mold resin layer. The elastic modulus of the buffer film is set lower than that of the mold resin layer.

According to the semiconductor device of the present invention, because a buffer film is provided at the interface between side faces of the metal island on which the semiconductor chip is mounted and the mold resin layer as described above and the elastic modulus of the buffer film is lower than those of the metal island and the mold resin layer, it is possible to suppress the peeling-off that might occur between the metal island and the mold resin film due to a difference of the shrinkage ratio between those items, thereby the product (semiconductor device) reliability is improved.

The present invention, therefore, can provide a semiconductor device capable of suppressing the peeling-off that might occur between the metal island and the mold resin layer due to a difference of the shrinkage ratio between those items, thereby improving the product reliability.

### BRIEF DESCRIPTION OF THE DRAWINGS

FIG. 1 is an explanatory cross sectional view of a semiconductor device in a first embodiment;

FIG. 2 is a graph that shows a relationship between temperatures and elastic modulus (between a buffer film and a mold resin layer) in the semiconductor device in the first embodiment;

FIG. 3 is an explanatory cross sectional view of a semiconductor device in a second embodiment;

FIG. 4 is an explanatory cross sectional view of the semiconductor device in a process with respect to a manufacturing method in the second embodiment;

FIG. 5 is an explanatory cross sectional view of the semiconductor device in another process with respect to the manufacturing method in the second embodiment;

FIG. 6 is an explanatory cross sectional view of the semiconductor device in still another process with respect to the manufacturing method in the second embodiment;

FIG. 7 is an explanatory cross sectional view of a semiconductor device in another example;

FIG. 8 is a cross sectional view of the semiconductor device for describing the problems to be solved by the present invention;

FIG. 9 is an explanatory cross sectional view of a conventional semiconductor device;

FIG. 10 is an explanatory cross sectional view of another conventional semiconductor device; and

FIG. 11 is an explanatory cross sectional view of still another conventional semiconductor device.

### DETAILED DESCRIPTION OF THE PREFERRED EMBODIMENTS

Hereunder, there will be described the embodiments of the present invention with reference to the accompanying drawings. In those drawings, the same reference numerals will be used for the same components, avoiding redundant description.

### First Embodiment

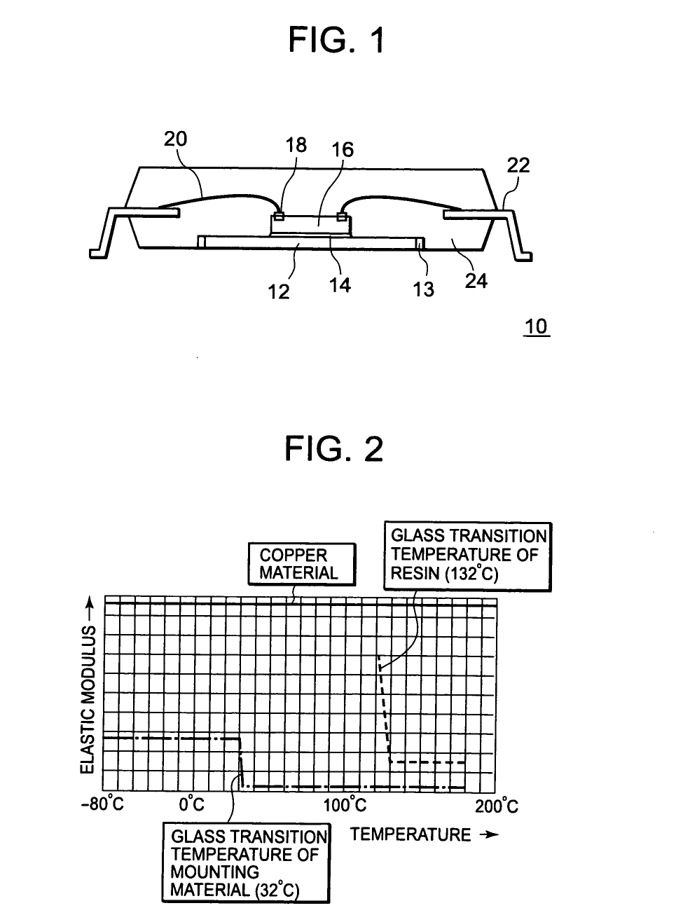

A semiconductor device 10 in this first embodiment includes a metal island 12 and a semiconductor chip mounted on the metal island 12 as shown in FIG. 1.

And a buffer film 13 is formed at the interface between each side face of the metal island 12 and the mold resin layer 24. The elastic modulus of the buffer film 13 is lower than that of the mold resin layer 24.

The metal island 12 includes copper, aluminum, ferrum, etc. The buffer film 13 of which elastic modulus is lower than that of the mold resin layer 24 may also be formed with a mounting material or the like. The mounting material may be any of thermosetting resin compositions such as epoxy resin, polyimide resin, etc. The thermosetting resin composition may include grains of such metal as nickel or the like.

The semiconductor chip 16 is mounted on the metal island 12 through a mounting material 14. A pad 18 and a lead 22 of the semiconductor chip 16 are connected electrically to each other through a wire 20.

The metal island 12, the semiconductor chip 16, and part of the lead 22 are sealed by a mold resin layer 24. The mold resin layer 24 can be formed with a composition of such thermosetting resin as epoxy resin, silicon resin, urethane resin, etc. and has an elastic modulus higher than that of the buffer film 13. The back side of the metal island 12 is exposed from the mold resin layer 24.

The semiconductor device 10 can be manufactured with use of any of ordinary methods.

The following will describe the effect of the semiconductor device in this first embodiment.

In this first embodiment, a buffer film 13 is provided at the interface between each side face of the metal island on which the semiconductor chip 16 is mounted and the mold resin layer 24. The elastic modulus of the buffer film 13 is lower than that of the mold resin layer 24.

Consequently, it is possible to suppress the peeling-off that might occur between the metal island 12 and the mold resin layer 24 due to a difference of the shrinkage ratio between those items, which appears remarkably in the horizontal direction, thereby the reliability of the semiconductor device is improved.

In this first embodiment, the buffer film 13 can be made of a mounting material 14.

Consequently, there is no need to use any other materials for the buffer material 13 and accordingly the manufacturing cost of the semiconductor device can be reduced.

Furthermore, in this first embodiment, the glass transition temperature of the buffer film 13 is lower than that of the mold resin layer 24.

Consequently, it is possible to suppress the peeling-off that might occur between the metal island 12 and the mold resin layer 24 due to a difference of the shrinkage ratio between those items more effectively. Thus the reliability of the semiconductor device can be more improved.

Hereinafter, there will be described an effect to be achieved by a difference of the glass transition temperature between the buffer film 13 and the mold resin layer 24 with reference to FIG. 2. In the example shown in FIG. 2, the mounting material 14 is used as the buffer film 13.

FIG. 2 shows a relationship between elastic modulus and temperatures in a case where copper is used for the metal island 12, one-pack type acrylic, a liquid epoxy resin composition (main agent: one-pack acrylic, liquid epoxy resin; reaction reducer: acrylate; curing agent: organic superoxide; and filler: silver (product name EN4900, Hitachi Chemical Co., Ltd.)) is used for the mounting material 14, and thermosetting epoxy resin (produced by Sumitomo Bakelite Co., Ltd.) is used for the mold resin layer 24 respectively. The glass transition temperature of the mounting material 14 is 32° C. and that of the mold resin layer is 132° C.

In the estimated operation temperature range (around −60° C. to 200° C.) of the semiconductor device 10, if the temperature falls, the elastic modulus of the mounting material 14 is kept lower than that of the mold resin layer 24. The elastic modulus of the mold resin layer 24 begins to rise at 132° C., which is the glass transition temperature while the mounting material 14 keeps its low elastic modulus up to 32° C., which is its glass transition temperature. This means that the glass transition temperature of the mounting material 14 is lower than that of the mold resin layer 24, so that the elastic modulus of the mounting material 14 is kept even when the elastic modulus of the mold resin layer 24 rises.

Because the semiconductor device 10 uses the buffer film 13 having an elastic modulus lower than that of the mold resin layer 24 and a glass transition temperature lower than that of the mold resin layer 24 such way, the difference of the elastic modulus between the buffer film 13 and the mold resin layer 24 comes to appear more remarkably. Consequently, the buffer film 13 can absorb the difference of the shrinkage between the metal island 12 and the mold resin layer 24, thereby the peeling-off that might occur between those items can be suppressed more effectively.

The glass transition temperature of the buffer film 13 should be 50° C. and under, more preferably be 40° C. and under. Although the lower limit value is not specified specially, the value should be −20° C. and over.

Because the buffer film 13 having such a low glass transition temperature is used, the difference of the elastic modulus between the buffer film 13 and the mold resin layer 24 comes to appear more remarkably, thereby the peeling-off between the metal island 12 and the mold resin layer 24 can be suppressed more effectively.

### Second Embodiment

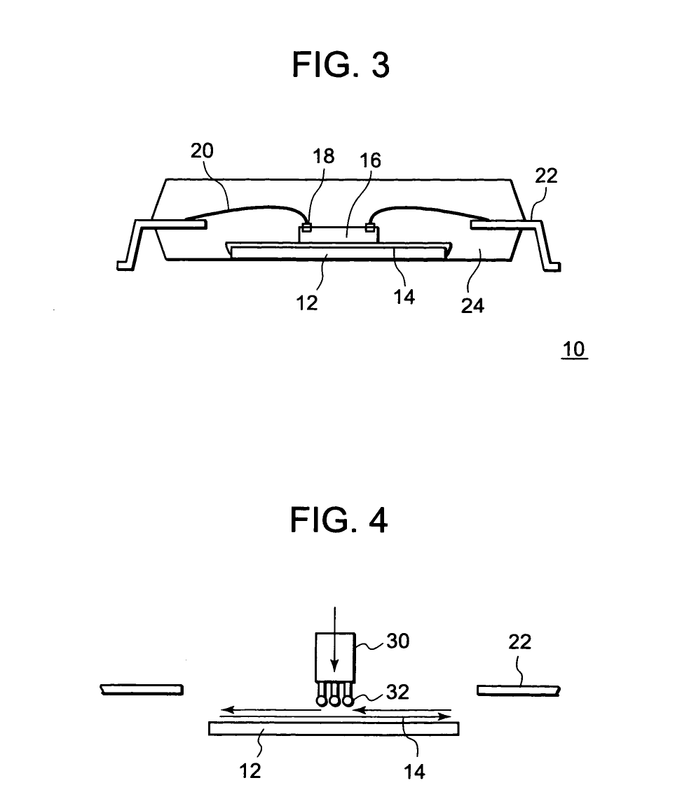

Unlike the semiconductor device in the first embodiment, the semiconductor device 10 in this second embodiment includes a buffer film at the interface between the mold resin layer 24 and a section from the top face to each side face of the metal island 12 as shown in FIG. 3. In this second embodiment, the buffer film is made of the mounting material 14.

Next, there will be described a manufacturing method of the semiconductor device 10 in this second embodiment with reference to the accompanying drawings.

At first, as shown in FIG. 4, a mounting material 32 is coated all over the surface of the metal island 12 with use of a jig (dispenser 30), thereby obtaining the mounting material 14. At this time, the amount of coating is adjusted so that part of the mounting material 32 covers the side faces of the metal island 12.

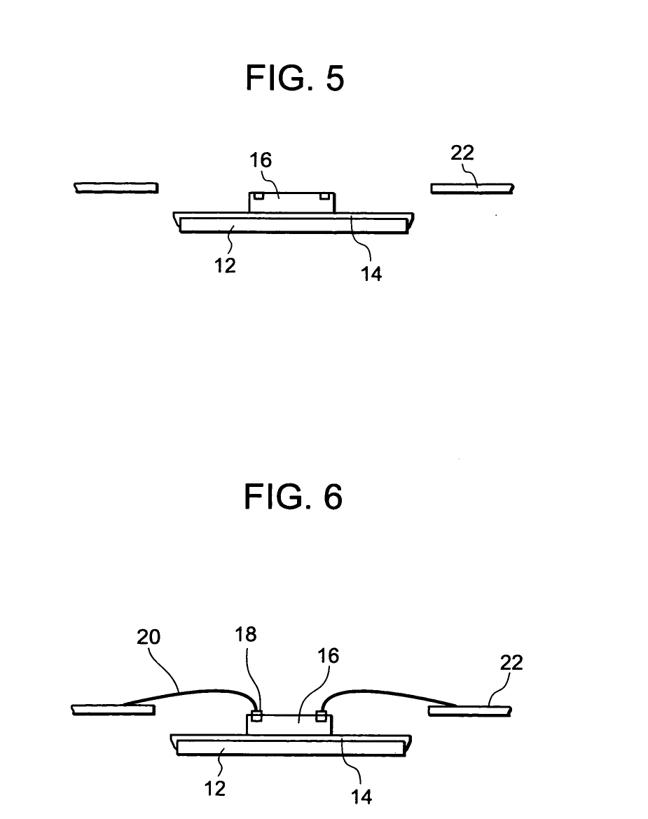

After this, a semiconductor chip 16 is mounted in the center of the surface of the metal island 12 as shown in FIG. 5, then the semiconductor chip 16 is connected to the metal island 12 through the mounting material 14.

Then, as shown in FIG. 6, the pad 18 and the lead 22 of the semiconductor chip 16 are wire-bonded and connected to each other through a wire 20.

Then, the semiconductor chip 16 mounted on the metal island 12 and the lead 22 are placed in a metal mold (not shown). Furthermore, epoxy resin is injected into the metal mold to form a mold resin layer 24 having a predetermined shape, then the lead 22 is formed into a predetermined shape, thereby completing the semiconductor device (product) as shown in FIG. 1.

Hereunder, there will be described the effect of this second embodiment.

This second embodiment can obtain not only the effect of the first embodiment, but also the following effect.

In this second embodiment, a buffer film (mounting material 14) is formed at the interface between the top and side faces of the metal island 12 and the mold resin layer 24.

Because the mounting material 14 is also provided on the top face of the metal island 12, the adhesion between the metal island 12 and the mold resin layer 24 is more improved. Consequently, the peeling-off that might occur between the metal island 12 and the mold resin layer 24 can be suppressed effectively, thereby the reliability of the semiconductor device is improved.

Furthermore, the buffer film can be formed together with the mounting material 14 as described above, and so the productivity of the semiconductor device can also be improved.

While the preferred form of the present invention has been described, it is to be understood that modifications will be apparent to those skilled in the art without departing from the spirit of the invention.

For example, while the mounting material 14 is provided at the side faces of the metal island 12 in this second embodiment, the material 14 may be provided at least only at one side face of the metal island 12.

In this second embodiment, a resin layer other than the mounting material 14 may be used as the buffer film having an elastic modulus lower than that of the mold resin layer 24.

In this second embodiment, the surface of the metal island 12 may be roughened by plating or the like. In this case, the mounting material overspreads in uniform on the surface of the metal island 12 and the adhesion between the metal island 12 and the mounting material 14 is improved.

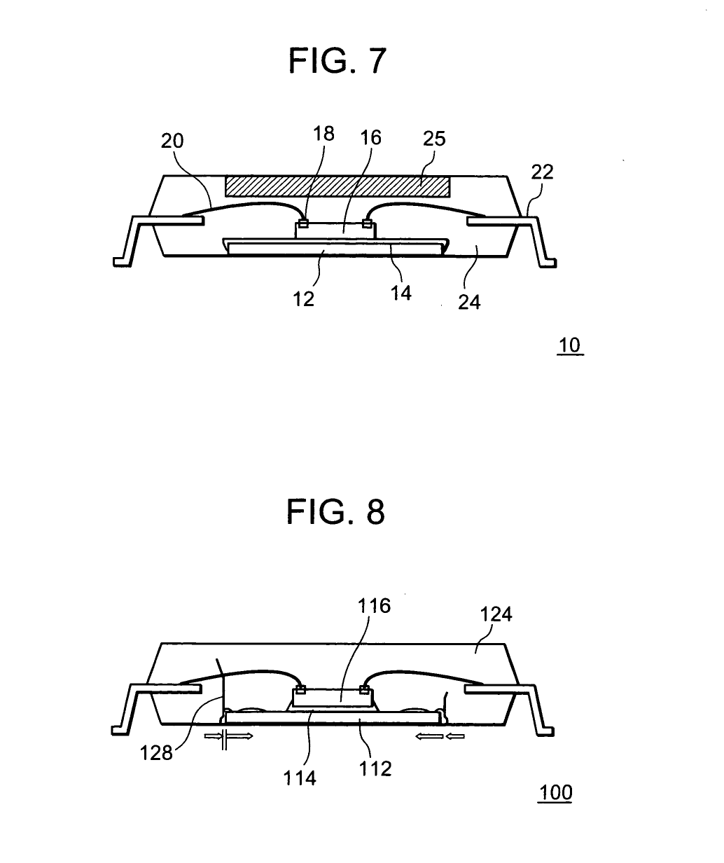

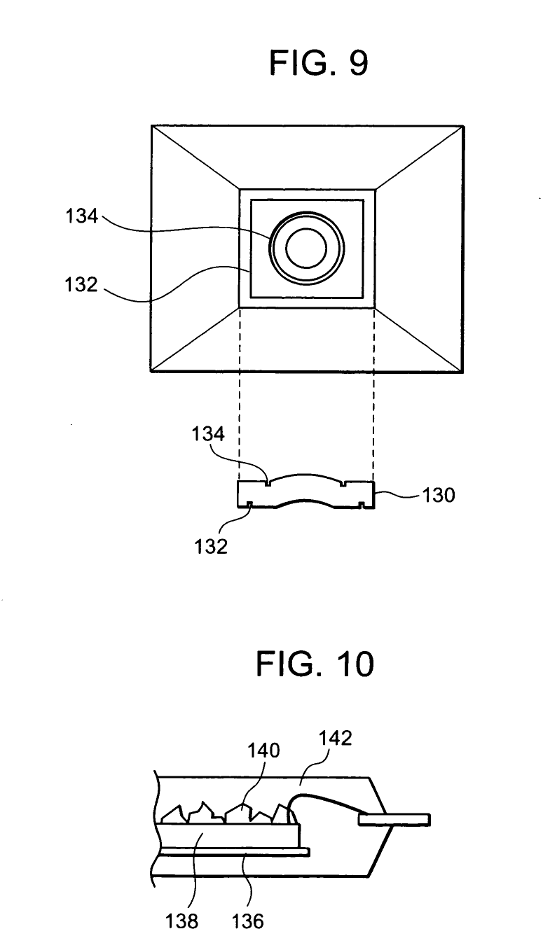

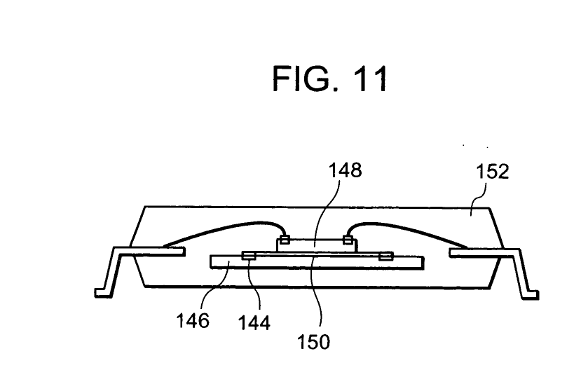

In this second embodiment, a heat spreader 25 that is a heat radiating metal plate may be provided in the mold resin layer 24 and separated from the semiconductor chip 16 and the wire 20 as shown in FIG. 7. The top face of the heat spreader 25 may be exposed from the mold resin layer 24 as shown in FIG. 7. The heat spreader 25 includes copper, aluminum, ferrum, etc.

What is claimed is:

1. A semiconductor device, comprising:
an island;
a semiconductor chip mounted on one of the surfaces of the island; and
a resin layer that seals the island and the semiconductor chip,
wherein a buffer film having an elastic modulus that is lower than that of the resin layer is formed at an interface between a side surface of the island and the resin layer.

2. The semiconductor device according to claim 1,
wherein the other surface of the island is exposed from the resin layer.

3. The semiconductor device according to claim 1,
wherein the buffer film is formed at an interface between one surface of the island and the resin layer.

4. The semiconductor device according to claim 1,
wherein the buffer film is made of a mounting material.

5. The semiconductor device according to claim 4,
wherein the mounting material is a one-pack type acrylic or liquid epoxy resin composition.

6. The semiconductor device according to claim 5,
wherein the resin layer is made of thermosetting epoxy resin.

7. The semiconductor device according to claim 1,
wherein the glass transition temperature of the buffer film is lower than that of the resin layer.

8. The semiconductor device according to claim 1,
wherein the device has a metal plate formed in the resin layer and separated from the semiconductor chip.

9. The semiconductor device according to claim 1,
wherein the island is buried in the resin layer.
